(19) United States
(12) Patent Application Publication
(10) Pub. No.: US 2024/0395514 A1
(43) Pub. Date: Nov. 28, 2024

(54) MULTI-CHAMBER PROCESSING TOOL WITH ENHANCED THROUGHPUT

(71) Applicant: Applied Materials, Inc., Santa Clara, CA (US)

(72) Inventors: Prashant AGARWAL, Singapore (SG); Junqi WEI, Singapore (SG); Ananthkrishna JUPUDI, Singapore (SG); Clinton GOH, Singapore (SG); Tuck Foong KOH, Singapore (SG); Kai Liang LIEW, Singapore (SG)

(21) Appl. No.: 18/202,335

(22) Filed: May 26, 2023

(51) Int. Cl. H01J 37/32; C23C 14/02; C23C 14/34; C23C 14/54; C23C 14/56; C23C 14/58; H01L 21/324; H01L 21/67; H05B 6/80

(52) U.S. Cl. CPC H01J 37/32899; C23C 14/021; C23C 14/34; C23C 14/541; C23C 14/566; C23C 14/58; H01J 37/32357; H01J 37/32513; H01L 21/324; H01L 21/67201; H01L 21/67207; H05B 6/80; H01J 37/32816; H01J 2237/022; H01J 2237/182; H01J 2237/186; H01J 2237/201; H01J 2237/20285

(57) ABSTRACT

Embodiments of multi-chamber processing tools are provided herein. In some embodiments, a multi-chamber processing tool includes: a factory interface configured to receive a substrate; a pre-heat chamber directly coupled to the factory interface; a load lock chamber coupled to the factory interface and having a first slit valve disposed therebetween, wherein the load lock chamber is coupled to a pump configured to create a vacuum environment when the first slit valve is in a closed position; a degas chamber coupled to the factory interface and having a second slit valve, wherein the degas chamber is coupled to a second pump configured to create a vacuum environment when the second slit valve is in a closed position, and wherein the degas chamber includes a heat source; one or more process chambers; and a transfer chamber coupled to the load lock chamber, the degas chamber, and the one or more process chambers.

### FIELD

Embodiments of the present disclosure generally relate to substrate processing equipment.

### BACKGROUND

The process of forming semiconductor devices is commonly done in a multi-chamber processing system (e.g., a cluster tool) which has the capability to process substrates, (e.g., semiconductor wafers) in a controlled processing environment. A typical controlled processing environment includes a system that has a transfer chamber which houses a substrate transfer robot configured to transport substrates among a load lock chamber and multiple vacuum processing chambers, which are connected to the transfer chamber. The controlled processing environment has many benefits, such as minimizing contamination of the substrate surfaces during transfer and during completion of the various substrate processing steps. Processing in a controlled environment thus reduces the number of generated defects and improves device yield.

For deposition of metal films in semiconductor fabrication and packaging, a thermal degas process is often conducted prior to metal deposition to ensure clean substrate surfaces free of residues. However, the inventors have observed that in cluster tools having a load lock chamber and degas chamber directly coupled to a factory interface, a bottleneck can be at the load lock chamber which is configured for moving substrates into the transfer chamber to facilitate processing and out from the transfer chamber back to the factory interface.

Accordingly, the inventors have provided herein embodiments of improved multi-chamber processing tools and improved methods directed at processing substrates using multi-chamber processing tools.

### SUMMARY

Embodiments of multi-chamber processing tools are provided herein. In some embodiments, a multi-chamber processing tool includes: a factory interface configured to receive a substrate and having a robot disposed therein for transferring the substrate; a pre-heat chamber directly coupled to the factory interface and configured to heat the substrate at atmospheric temperature; a load lock chamber coupled to the factory interface and having a first slit valve disposed therebetween to selectively seal the load lock chamber from the factory interface, wherein the load lock chamber is coupled to a pump configured to create a vacuum environment when the first slit valve is in a closed position; a degas chamber coupled to the factory interface and having a second slit valve disposed therebetween to selectively seal the degas chamber from the factory interface, wherein the degas chamber is coupled to a second pump configured to create a vacuum environment when the second slit valve is in a closed position, and wherein the degas chamber includes a heat source configured to remove contaminants from the substrate; one or more process chambers configured to process the substrate; and a transfer chamber coupled to the load lock chamber, the degas chamber, and the one or more process chambers, wherein the transfer chamber includes a transfer robot configured to facilitate transferring the substrate from the degas chamber to the load lock chamber and the one or more process chambers.

In some embodiments, a method of processing a substrate includes: transferring the substrate to a factory interface of a multi-chamber processing tool having a first pressure therein; pre-heating the substrate in a pre-heat chamber directly coupled to the factory interface; transferring the substrate to a degas chamber having a heat source and coupled to the factory interface via a slit disposed between the degas chamber and the factory interface; closing the slit; pumping down the degas chamber to a second pressure therein, wherein the second pressure is less than the first pressure; transferring the substrate to one or more process chambers; transferring the substrate to a load lock chamber; and transferring the substrate to the factory interface.

In some embodiments, a computer readable medium comprising one or more processors, that when executed, perform a method of processing a substrate includes: transferring the substrate to a factory interface of a multi-chamber processing tool having a first pressure therein; pre-heating the substrate in a pre-heat chamber directly coupled to the factory interface; transferring the substrate to a degas chamber having a heat source and coupled to the factory interface via a slit disposed between the degas chamber and the factory interface; closing the slit; pumping down the degas chamber to a second pressure therein, wherein the second pressure is less than the first pressure; transferring the substrate to one or more process chambers; transferring the substrate to a load lock chamber; and transferring the substrate to the factory interface.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic top view of a multi-chamber processing tool in accordance with at least some embodiments of the present disclosure.

FIG. 2 depicts a schematic side view of a multi-chamber processing tool in accordance with at least some embodiments of the present disclosure.

FIG. 3 depicts a schematic side view of a degas chamber in accordance with at least some embodiments of the present disclosure.

FIG. 4 depicts a flow chart of a method of method of processing a substrate in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of multi-chamber processing tools and methods directed at processing substrates using multi-chamber processing tools are provided herein. The multi-chamber processing tool may be used for performing semiconductor fabrication processes such as metal deposition, or the like. The multi-chamber processing tool generally includes a factory interface coupled to a degas chamber and one or more deposition chambers. The degas chamber is coupled directly to a factory interface of the multi-chamber process tool and is advantageously configured to perform degas processes as well as for use as a load lock chamber to facilitate transferring substrates to and from the factory interface to advantageously increase system throughput and decrease processing costs.

The degas chamber is coupled to a pump and venting system to selectively pressurize the degas chamber to atmospheric pressure when receiving substrates from the factory interface and to a pressure lower than the atmospheric pressure prior to transferring the substrate to one or more process chambers of the multi-chamber processing tool for further processing. The degas chamber conventionally was not used as a load lock chamber or subjected to atmospheric pressure of the factory interface due to contamination issues. However, the inventors have observed that with adequate time spent on venting the degas chamber, contamination issues may be minimized. The inventors have found that the additional time spent on venting the degas chamber is less than the time gained from avoiding the bottleneck of the degas chamber when not configured as a load lock chamber. The multi-chamber processing tool further includes a pre-heat chamber coupled to the factory interface so that substrates may be preheated prior to degassing in the degas chamber, advantageously reducing substrate time spent in the degas chamber, thereby further increasing system throughput.

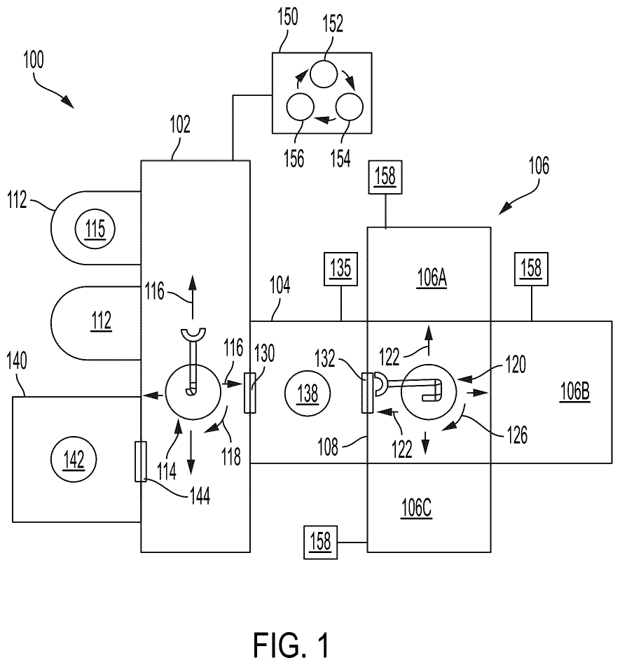

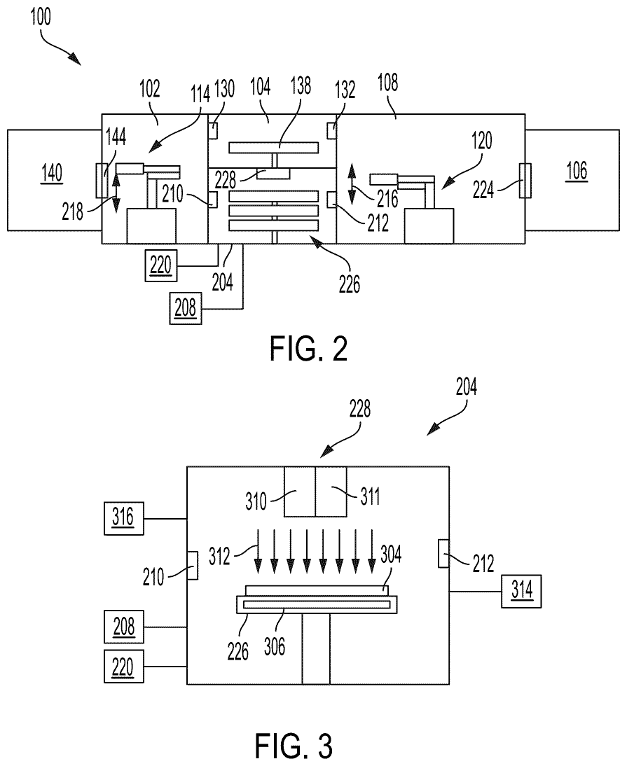

FIG. 1 depicts a schematic top view of a multi-chamber processing tool 100 in accordance with at least some embodiments of the present disclosure. FIG. 2 depicts a schematic side view of a multi-chamber processing tool 100 in accordance with at least some embodiments of the present disclosure. The multi-chamber processing tool 100 generally includes a factory interface 102 configured to receive a substrate 115 (e.g., semiconductor wafers, or the like) and having a robot 114 disposed therein for transferring the substrate 115. In some embodiments, one of more loadports 112 are coupled to the factory interface 102. The one or more loadports 112 are configured for receiving one or more substrates such as the substrate 115. For example, the one or more loadports 112 may be configured for receiving front opening unified pods (FOUPs) which are containers for holding one or more substrates. An internal volume of the factory interface 102 is generally kept at atmospheric pressure.

A pre-heat chamber 140 is directly coupled to the factory interface 102 and configured to heat the substrate 115 at atmospheric temperature. The pre-heat chamber 140 includes a substrate support 142 for holding the substrate 115 and a suitable heat source for heating the substrate 115. In some embodiments, the suitable heat source may be configured to heat the substrate 115 to a temperature of about 100 to about 400 degrees Celsius. A slit valve 144 may be disposed between the pre-heat chamber 140 and the factory interface 102 and configured to selectively seal the pre-heat chamber 140 from the factory interface 102 and to facilitate transferring the substrate 115 therebetween. In some embodiments, the pre-heat chamber 140 is disposed on a same side of the factory interface 102 as the one or more loadports 112.

A load lock chamber 104 is coupled to the factory interface 102 and includes a slit valve 130 disposed therebetween to selectively seal the load lock chamber 104 from the factory interface 102. The load lock chamber 104 is coupled to a pump 135 configured to create a vacuum environment when the slit valve 130 is in a closed position. The load lock chamber 104 generally provides a vacuum interface between the factory interface 102 and a transfer chamber 108 coupled to the load lock chamber 104 on a side opposite the factory interface 102. A slit valve 132 is disposed between the load lock chamber 104 and the transfer chamber 108 to selectively seal the load lock chamber 104 from the transfer chamber 108. The load lock chamber 104 includes a substrate holder 138 configured to hold or support the substrate 115 or a plurality of substrates. In some embodiments, the load lock chamber 104 is disposed on a side of the factory interface 102 different than the pre-heat chamber 140. All of the slit valves disclosed herein may comprise a door and an actuator coupled to the door to selectively open or close a slit opening. The actuator is generally configured for linear motion or L-motion.

A degas chamber 204 is directly coupled to the factory interface 102. In some embodiments, the pre-heat chamber 140 is disposed on a side of the factory interface 102 opposite the degas chamber 204. In some embodiments, the load lock chamber 104 and the degas chamber 204 are in a stacked configuration. For example, the load lock chamber 104 may be disposed vertically above, or stacked on top of, the degas chamber 204. The degas chamber 204 includes a slit valve 210 disposed between the degas chamber 204 and the factory interface 102 to selectively seal the degas chamber 204 from the factory interface 102. The degas chamber 204 includes a slit valve 212 disposed between the degas chamber 204 and the transfer chamber 108 to selectively seal the degas chamber 204 from the transfer chamber 108.

The degas chamber 204 is coupled to a second pump 208 configured to create a vacuum environment when the slit valve 210 is in a closed position. The degas chamber 204 includes a heat source 228 configured to remove contaminants from the substrate 115 and a substrate support 226 for supporting one or more substrates (e.g., multiple ones of the substrate 115). In some embodiments, the degas chamber 204 is larger than the load lock chamber 104. In some embodiments, the degas chamber 204 includes a vent 220 open to atmospheric pressure for pressurizing the degas chamber 204 to atmospheric pressure prior to receiving the substrate 115 from the factory interface 102. In some embodiments, the degas chamber 204 vents via the factory interface 102. In some embodiments, as shown in FIG. 2, the vent 220 is disposed outside of an interface between the factory interface 102 and the degas chamber 204. In some embodiments, the vent 220 may include a filter to reduce or prevent contamination of the degas chamber 204.

The robot 114 is configured to facilitate transferring substrates between the one or more loadports 112, the pre-heat chamber 140, the degas chamber 204, and the load lock chamber 104. In some embodiments, the robot 114 may be configured to move in an axial direction 116, for example, via an arm that moves in an axial direction, via wheels or tracks that move the robot 114 in an axial direction, or a combination of an arm, wheels, or tracks. The robot 114 may be configured to move in a rotational direction 118. In some embodiments, at least two of the slit valve 144 of the pre-heat chamber 140, the slit valve 210 of the degas chamber 204, and the slit valve 130 of the load lock chamber 104 are disposed at different vertical heights. Accordingly, in some embodiments, the robot 114 is configured to move in a vertical direction 218, for example, to transfer substrates between the pre-heat chamber 140, the load lock chamber 104, and the degas chamber 204. In some embodiments, the robot 114 comprises multiple blades, each blade mounted on an independently controllable robot arm mounted on the same robot base. For example, the multiple blades may include one blade for transferring a substrate from the load lock chamber 104 to the one or more loadports 112 and a second blade for transferring a second substrate from the pre-heat chamber 140 to the degas chamber 204.

The transfer chamber 108 is coupled to the load lock chamber 104, the degas chamber 204, and one or more process chambers 106 and provides an interface to transfer, or shuttle, substrates therebetween to perform a suitable process. The transfer chamber 108 includes a transfer robot 120 configured to facilitate transferring the substrate 115 between the degas chamber 204, the one or more process chambers 106, and the load lock chamber 104. In some embodiments, the transfer chamber 108 may be a polygonal structure having a plurality of sidewalls, a bottom and a lid. The plurality of sidewalls may have openings formed therethrough and are configured to connect with the one or more process chambers 106, the degas chamber 204, and the load lock chamber 104.

In some embodiments, the transfer robot 120 may be mounted in the transfer chamber 108 at a robot port formed on the bottom of the transfer chamber 108. In some embodiments, the transfer robot 120 may be configured to move in an axial direction 122, for example, via an arm that moves in the axial direction 122, via wheels or tracks that move the transfer robot 120 in the axial direction 122, or a combination of an arm, wheels, or tracks. In some embodiments, the transfer robot 120 is configured to move in a rotational direction 126. In some embodiments, the transfer robot 120 is capable of movement in the vertical direction 216. In some embodiments, the transfer robot 120 comprises multiple blades, each blade mounted on an independently controllable robot arm mounted on the same robot base of the transfer robot 120. For example, the multiple blades may include one blade for transferring a substrate from the degas chamber 204 to one of the one or more process chambers 106 and a second blade for transferring a second substrate from one of the one or more process chambers 106 to the load lock chamber 104.

The one or more process chambers 106 are configured to perform one or more processes on the substrate 115. All of the one or more process chambers 106 are directly coupled to the transfer chamber 108. Processes that may be performed in any of the one or more process chambers 106 may include deposition, cleaning, etching, implant, and thermal treatment processes, among others. In some embodiments, at least one of the one or more process chambers 106 is configured to perform a physical vapor deposition (PVD), or sputtering process, on the substrate 115, or on multiple substrates simultaneously. In some embodiments, the one or more process chambers 106 include a first physical vapor deposition (PVD) chamber 106B and a second PVD chamber 106C. In some embodiments, one or more process chambers 106 include a clean chamber 106A. The clean chamber 106A may perform any suitable cleaning process such as, for example, a sputtering clean process comprising an inert gas, such as argon. In some embodiments, the one or more process chambers 106 include one or more deposition chambers and a cleaning chamber. FIG. 1 depicts an illustrative embodiment of the arrangement of the one or more process chamber, however, any suitable arrangement of the one or more process chambers about the transfer chamber 108 is within the scope of the embodiments disclosed herein.

Typically, the one or more process chambers 106 comprise a sealed chamber having a slit valve 224 disposed at an interface with the transfer chamber 108 and having a pedestal for supporting the substrate 115. The pedestal may include a substrate support that has electrodes disposed therein to electrostatically hold the substrate 115 against the substrate support during processing. For processes tolerant of higher chamber pressures, the pedestal may alternately include a substrate support having openings in communication with a vacuum source for securely holding the substrate 115 against the substrate support during processing. Each of the one or more process chambers 106 may include a gas delivery system 158 for delivering process gases to each respective one of the one or more process chambers 106.

A controller 150 controls the multi-chamber processing tool 100 described herein. The controller 150 may use a direct control of the multi-chamber processing tool 100, or alternatively, by controlling the computers (or controllers) associated with the multi-chamber processing tool 100. In operation, the controller 150 enables data collection and feedback from the multi-chamber processing tool 100 to optimize performance of the multi-chamber processing tool 100. The controller 150 generally includes a Central Processing Unit (CPU) 152, a memory 154, and a support circuit 156. The CPU 152 may be any form of a general-purpose computer processor that can be used in an industrial setting. The support circuit 156 is conventionally coupled to the CPU 152 and may comprise a cache, clock circuits, input/output subsystems, power supplies, and the like. Software routines, such as a method as described below may be stored in the memory 154 and, when executed by the CPU 152, transform the CPU 152 into a specific purpose computer (controller 150). The software routines may also be stored and/or executed by a second controller (not shown) that is located remotely from the multi-chamber processing tool 100.

The memory 154 is in the form of computer-readable storage media that contains instructions, when executed by the CPU 152, to facilitate the operation of the semiconductor processes and equipment. The instructions in the memory 154 are in the form of a program product such as a program that implements the method of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

FIG. 3 depicts a schematic side view of a degas chamber 204 in accordance with at least some embodiments of the present disclosure. The degas chamber 204 can include the substrate support 226 for supporting a substrate 304, such as the substrate 115. The substrate support 226 can be composed of standard materials, such as aluminum, quartz, ceramic or stainless steel. Further, the substrate support 226 can be designed to support substrates of any size, such as a 300 mm substrate. Various heating and cooling devices may be embedded in or positioned in connection with the substrate support 226 or the degas chamber 204 so as to deliver heating or cooling to the substrate 304. The substrate 304 can be any composition useable for semiconductor applications, such as a silicon, epoxy or quartz substrate.

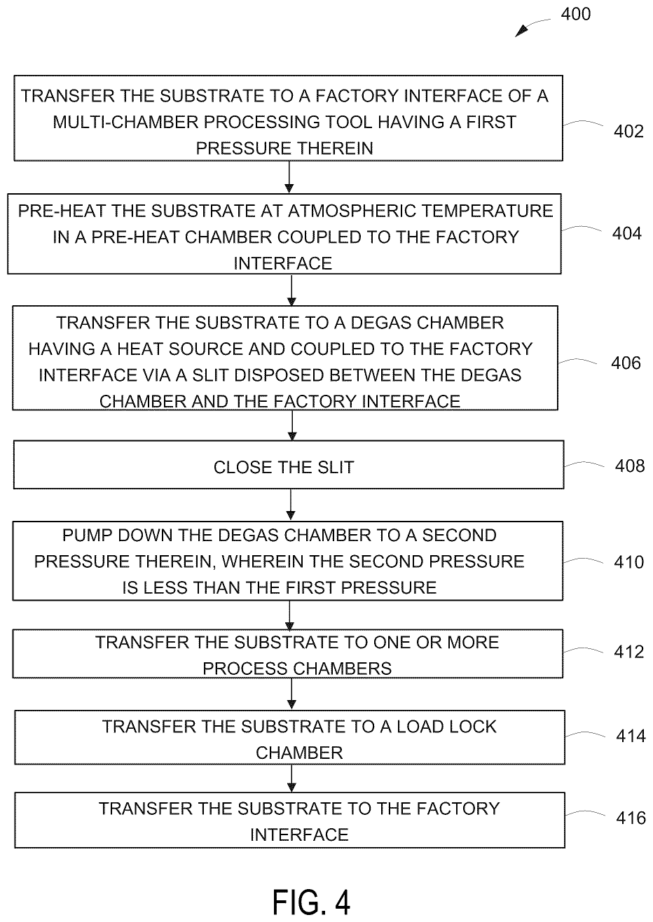

The degas chamber 204 includes the heat source 228 such as a heat source 306 depicted in FIG. 4 as being embedded in the substrate support 226. Though the heat source 306 is depicted in FIG. 4 as being a resistive heat source, which may comprise one or more heating elements embedded in the substrate support 226, the heat source 306 may be any heat source applicable to degassing of a substrate, such as an infrared heat lamp heat source, or the like. The heat from the heat source 306 may be delivered directly to the substrate 304 or indirectly by changing the temperature of the chamber. The heat source 306 can be designed to heat and maintain the substrate at a stable temperature, such as a temperature between about 100 to about 400 Celsius. The heat source 306 may be of any design and positioned in any position which will allow energy to be delivered for heating the substrate 304.

In addition to the heat source 306, or alternatively to the heat source 306, the heat source 228 may be a microwave heat source that includes, for example, a microwave power source 310. The microwave power source 310 can be selected from all available microwave power sources, including magnetrons, klystrons, gyrotrons, and traveling wave tubes. The heat source 228 can also include a microwave cavity 311 associated with the microwave power source 310. The microwave cavity 311 can be either a single mode, multi-mode cavity or combinations thereof. The microwave cavity 311 can receive power from the microwave power source 310. The use of microwave radiation can allow for a lower temperature and higher throughput degassing procedure than can be achieved from standard thermal degassing units. Further, microwave radiation can allow for degassing of a single substrate or batch degassing of a plurality of substrates when the substrate support 226 is configured for supporting a plurality of substrates, for example, a plurality of substrates in a vertically spaced apart orientation, as depicted in FIG. 2.

Microwave energy 312 may be delivered from the heat source 228 and can include continuous sweeping of frequencies over an available frequency range. Continuous sweeping can prevent charge buildup in metal layers, thus reducing the potential for arcing and subsequent damage. Frequency sweeping is often carried out by selecting a center frequency and then rapidly sweeping the frequency in a substantially continuous way over some range. Typically, frequency sweeping can include frequencies in the range of +/−5% of the center frequency, although the range can vary depending on such factors as the type of microwave source and the overall size of the cavity compared to the microwave wavelength.

The degas chamber 204 can further include a gas source 314. The gas source 314 can deliver an inert gas, such as a gas comprising argon or helium. The gas source 314 can deliver gas to the degas chamber 204 at a specified flow rate based on the size of the degas chamber 204 and the size of the substrate 115 being processed. The gas source 314 can be directly connected with the degas chamber 204 or indirectly delivered, such as a noble gas being converted to plasma in a remote plasma source prior to delivery to the degas chamber 204. The gas source 314 can be positioned so as to deliver gas over the substrate 304, so as to both cool the substrate 304 and to deliver the selected inert gas.

The degas chamber 204 can also include a plasma source 316. The plasma source 316 can produce plasma from an inert gas, such as from a gas including argon or helium. The plasma source 316 can produce the plasma inside the chamber or the plasma can be produced in a remote source. The plasma source 316 can receive gas flow from the gas source 314 or from a separate gas source (not shown). The inert gas or combination including an inert gas used in the plasma source 316 need not be the same inert gas or combination including an inert gas that is used in the gas source 314. The plasma source 316 can use plasma formed by all available plasma production techniques, including inductively coupled plasma, capacitively coupled plasma or microwave plasma. The plasma source 316 can deliver plasma directed at the substrate 304 or generally to the degas chamber 204. The second pump 208 can be applied to both maintain a vacuum, such as during plasma processing and to remove unwanted byproducts of the degassing.

FIG. 4 depicts a flow chart of a method 400 of processing a substrate in accordance with at least some embodiments of the present disclosure. At 402, the method 400 includes transferring the substrate (e.g., substrate 115) to a factory interface (e.g., factory interface 102) of a multi-chamber processing tool (e.g., multi-chamber processing tool 100) having a first pressure therein. In some embodiments, the first pressure is atmospheric pressure. The substrate is then transferred to a pre-heating chamber (e.g., pre-heat chamber 140) that is coupled to the factory interface.

At 404, the method 400 includes pre-heating the substrate in the pre-heat chamber. The pre-heating may be performed at the first pressure. In some embodiments, pre-heating comprises heating the substate to a temperature of about 100 to about 400 degrees Celsius. In some embodiments, pre-heating comprises heating the substate to a temperature of about 100 to about 200 degrees Celsius A robot (e.g., robot 114) disposed in the factory interface may be used to transfer the substrate into and out of the pre-heat chamber. In some embodiments, the pre-heat chamber may be configured to pre-heat a plurality of substrates.

At 406, the method 400 includes transferring the substrate to a degas chamber (e.g., degas chamber 204) having a heat source (e.g., heat source 228) and coupled to the factory interface via a slit (e.g., slit valve 210) disposed between the degas chamber and the factory interface. In some embodiments, when transferring the substrate to the degas chamber from the factory interface, the degas chamber internal pressure is at or near the first pressure. A second slit (e.g., slit valve 212) of the degas chamber is in the closed position when transferring one or more substrates into the degas chamber from the factory interface.

At 408, the method 400 includes closing the slit so that the degas chamber is sealed with respect to the factory interface. At 410, the method 400 includes pumping down the degas chamber to a second pressure therein, wherein the second pressure is less than the first pressure. Pumping down may be performed with a pump (e.g., second pump 208) that is in fluid communication with an internal volume of the degas chamber. In some embodiments, the method 400 includes heating the substrate in the degas chamber to a temperature of about 100 to about 400 degrees Celsius after closing the slit. In some embodiments, heating the substrate in the degas chamber comprises heating to a temperature of about 200 to about 400 degrees Celsius after closing the slit. In some embodiments, heating in the degas chamber is performed at a higher temperature than heating in the pre-heat chamber.

At 412, the method 400 includes transferring the substrate to one or more process chambers (e.g., one or more process chambers), for example, after opening the second slit. In some embodiments, transferring the substrate to the one or more process chambers is performed via a transfer chamber (e.g., transfer chamber 108). In some embodiments, transferring the substrate to one or more process chamber comprises transferring the substrate to a cleaning chamber (e.g., cleaning chamber 106A) and then transferring the substrate to a deposition chamber (e.g., one of deposition chambers 106B or 106C). In some embodiments, the method 400 includes transferring the substrate to a second deposition chamber (e.g., remaining one of deposition chamber 106B or 106C). The deposition chambers may be configured for depositing metal or metal alloys. For example, the deposition chambers may be PVD chambers configured for depositing, copper, titanium, tungsten, or the like, or alloys comprising copper, titanium, tungsten, or the like. For example, in some embodiments, the deposition chamber may be a titanium deposition chamber and the second deposition chamber may be a copper deposition chamber. In some embodiments, the one or more process chambers and the transfer chamber all have internal pressures less than the first pressure, for example, vacuum pressures.

At 414, the method 400 includes transferring the substrate to a load lock chamber (e.g., load lock chamber 104). The substrate is generally transferred between the degas chamber, the one or more process chambers, and the load lock chamber via a transfer chamber. At 416, the method 400 includes transferring the substrate to the factory interface for removal from the multi-chamber processing tool, for example, via one or more loadports (e.g., one or more loadports 112) coupled to the factory interface.

While the foregoing is directed to embodiments of the present disclosure, other and further embodiments of the disclosure may be devised without departing from the basic scope thereof.

1. A multi-chamber processing tool, comprising:
a factory interface configured to receive a substrate and having a robot disposed therein for transferring the substrate;
a pre-heat chamber directly coupled to the factory interface and configured to heat the substrate;
a load lock chamber coupled to the factory interface and having a first slit valve disposed therebetween to selectively seal the load lock chamber from the factory interface, wherein the load lock chamber is coupled to a pump configured to create a vacuum environment when the first slit valve is in a closed position;
a degas chamber coupled to the factory interface and having a second slit valve disposed therebetween to selectively seal the degas chamber from the factory interface, wherein the degas chamber is coupled to a second pump configured to create a vacuum environment when the second slit valve is in a closed position, and wherein the degas chamber includes a heat source configured to remove contaminants from the substrate;
one or more process chambers configured to process the substrate; and
a transfer chamber coupled to the load lock chamber, the degas chamber, and the one or more process chambers, wherein the transfer chamber includes a transfer robot configured to facilitate transferring the substrate from the degas chamber to the load lock chamber and the one or more process chambers.

2. The multi-chamber processing tool of claim 1, wherein the degas chamber is larger than the load lock chamber.

3. The multi-chamber processing tool of claim 1, wherein the pre-heat chamber is disposed on a side of the factory interface opposite the degas chamber.

4. The multi-chamber processing tool of claim 1, wherein the one or more process chambers include one or more deposition chambers and a cleaning chamber.

5. The multi-chamber processing tool of claim 1, wherein the load lock chamber and the degas chamber are in a stacked configuration.

6. The multi-chamber processing tool of claim 1, further comprising a gas delivery system for delivering process gases to the one or more process chambers.

7. The multi-chamber processing tool of claim 1, wherein the degas chamber includes a substrate support for supporting the substrate, and wherein the heat source comprises a microwave heat source or one or more heating elements disposed in the substrate support.

8. The multi-chamber processing tool of claim 1, wherein the degas chamber includes a substrate support for supporting a plurality of substrates.

9. The multi-chamber processing tool of claim 1, wherein the one or more process chambers include a first physical vapor deposition (PVD) chamber and a second PVD chamber.

10. A method of processing a substrate, comprising:
transferring the substrate to a factory interface of a multi-chamber processing tool having a first pressure therein;
pre-heating the substrate in a pre-heat chamber coupled to the factory interface;
transferring the substrate to a degas chamber having a heat source and coupled to the factory interface via a slit disposed between the degas chamber and the factory interface;
closing the slit;
pumping down the degas chamber to a second pressure therein, wherein the second pressure is less than the first pressure;
transferring the substrate to one or more process chambers;
transferring the substrate to a load lock chamber; and
transferring the substrate to the factory interface.

11. The method of claim 10, further comprising:
transferring the substrate to a pre-heat chamber coupled to the factory interface and heating the substrate in the pre-heat chamber at the first pressure prior to transferring the substrate to the degas chamber.

12. The method of claim 10, further comprising heating the substrate in the degas chamber to a temperature of about 100 to about 400 degrees Celsius after closing the slit.

13. The method of claim 10, wherein transferring the substrate to one or more process chamber comprises transferring the substrate to a cleaning chamber and then transferring the substrate to a deposition chamber.

14. The method of claim 10, wherein the substrate is transferred between the degas chamber, the one or more process chambers, and the load lock chamber via a transfer chamber.

15. The method of claim 14, wherein the one or more process chambers and the transfer chamber all have internal pressures less than the first pressure.

16. A computer readable medium comprising one or more processors, that when executed, perform a method of processing a substrate, comprising:
transferring the substrate to a factory interface of a multi-chamber processing tool having a first pressure therein;
pre-heating the substrate in a pre-heat chamber coupled to the factory interface;
transferring the substrate to a degas chamber having a heat source and coupled to the factory interface via a slit disposed between the degas chamber and the factory interface;
closing the slit;
pumping down the degas chamber to a second pressure therein, wherein the second pressure is less than the first pressure;
transferring the substrate to one or more process chambers;
transferring the substrate to a load lock chamber; and
transferring the substrate to the factory interface.

17. The method of claim 16, further comprising:
transferring the substrate to a pre-heat chamber coupled to the factory interface and heating the substrate in the pre-heat chamber at the first pressure prior to transferring the substrate to the degas chamber.

18. The method of claim 16, further comprising heating the substrate in the degas chamber to a temperature of about 100 to about 400 degrees Celsius after closing the slit.

19. The method of claim 16, wherein transferring the substrate to one or more process chamber comprises transferring the substrate to a cleaning chamber and then transferring the substrate to a deposition chamber.

20. The method of claim 16, wherein the substrate is transferred between the degas chamber, the one or more process chambers, and the load lock chamber via a transfer chamber.
